(19) United States
(12) Patent Application Publication
(10) Pub. No.: US 2026/0122922 A1
(43) Pub. Date: Apr. 30, 2026

(54) SEMICONDUCTOR DEVICE

(71) Applicant: Samsung Electronics Co., Ltd., Suwon-si (KR)

(72) Inventors: Yujin KIM, Suwon-si (KR); Jinwoo HAN, Suwon-si (KR)

(73) Assignee: Samsung Electronics Co., Ltd., Suwon-si (KR)

(21) Appl. No.: 19/280,563

(22) Filed: Jul. 25, 2025

(30) Foreign Application Priority Data
Oct. 30, 2024 (KR) 10-2024-0150280

(51) Int. Cl. H10B 80/00; H01L 23/00; H01L 25/065; H01L 25/18; H10B 12/00

(52) U.S. Cl. CPC H10B 80/00; H10B 12/30; H10W 90/00; H10W 90/792

(57) ABSTRACT

A semiconductor device includes a first structure including a substrate, and a second structure overlapping the first structure and including a peripheral circuit. The first structure includes a device isolation structure in the substrate, channel structures spaced apart from each other, an insulating pattern between the channel structures, bitlines extending in a vertical direction and contacting the channel structures, a gate electrode surrounding the channel structures, data storage structures contacting the channel structures, and a plate electrode connected to the data storage structures. The device isolation structure includes a first device isolation pattern overlapping the bitlines in the vertical direction, a second device isolation pattern overlapping the plate electrode in the vertical direction, and third device isolation patterns overlapping the insulating pattern in the vertical direction, and at least one of the first, second, and third device isolation patterns penetrates the substrate.

### CROSS-REFERENCE TO RELATED APPLICATION(S)

This application claims benefit of priority to Korean Patent Application No. 10-2024-0150280 filed on Oct. 30, 2024 in the Korean Intellectual Property Office, the disclosure of which is incorporated herein by reference in its entirety.

### BACKGROUND

Example embodiments of the present disclosure relate to a semiconductor device.

As demand for high performance, high speed, and/or multifunctionality of a semiconductor devices continually increases, integration density of a semiconductor devices has also increased. In the case of two-dimensional or planar semiconductor devices, integration density may be mainly determined by an area occupied by a unit memory cell array region. Accordingly, integration density may be limited by the capability of fine pattern formation processes. Accordingly, three-dimensional semiconductor devices including three-dimensionally arranged memory cells have been suggested.

### SUMMARY

Some example embodiments of the present disclosure provide a semiconductor device having a reduced size by reducing a thickness of a substrate through a polishing process on the substrate.

According to some example embodiments of the present disclosure, a semiconductor device includes a first structure including a substrate, and a second structure overlapping the first structure in a vertical direction and including a peripheral circuit. The first structure includes a device isolation structure in the substrate, channel structures extending on the substrate in a first horizontal direction, the channel structures spaced apart from each other in a second horizontal direction, the second horizontal direction intersecting the first horizontal direction, an insulating pattern between the channel structures, bitlines extending in the vertical direction on the substrate and contacting first ends of the channel structures, respectively, a gate electrode extending in the second horizontal direction and surrounding the channel structures, data storage structures contacting second ends of the channel structures, the second ends opposing to the first ends of the channel structures and spaced apart from each other in the second horizontal direction, and a plate electrode connected to the data storage structures and extending in the second horizontal direction and the vertical direction. The device isolation structure includes a first device isolation pattern overlapping the bitlines in the vertical direction, a second device isolation pattern overlapping the plate electrode in the vertical direction, and third device isolation patterns overlapping the insulating pattern in the vertical direction, spaced apart from each other in the second horizontal direction, and extending between the first device isolation pattern and the second device isolation pattern in the first horizontal direction, and at least one of the first device isolation pattern, the second device isolation pattern, and the third device isolation patterns penetrates the substrate.

According to some example embodiments of the present disclosure, a semiconductor device includes a substrate having a first region and a second region, a device isolation structure in the substrate, channel structures extending in a first horizontal direction on the first region of the substrate, spaced apart from each other in a second horizontal direction, the second horizontal direction intersecting the first horizontal direction, and further spaced apart in a vertical direction, the vertical direction intersecting the first horizontal direction and the second horizontal direction, bitlines extending in the vertical direction on the first region of the substrate, spaced apart from each other in the second horizontal direction, and contacting first ends of the channel structures, respectively, gate electrodes surrounding the channel structures spaced apart from each other in the second horizontal direction, spaced apart from the vertical direction, extending in the second horizontal direction, and including gate pads arranged in a staircase shape on the second region, data storage structures contacting second ends of the channel structures, the second ends opposing the first ends of the channel structures, and a plate electrode connected to the data storage structures, and the plate electrode extending in the second horizontal direction and the vertical direction. The device isolation structure includes a first device isolation pattern overlapping the bitlines in the vertical direction, and a second device isolation pattern overlapping the plate electrode in the vertical direction. At least one of a lower surface of the first device isolation pattern and a lower surface of the second device isolation pattern is coplanar with a lower surface of the substrate.

According to some example embodiments of the present disclosure, a semiconductor device includes a first structure including a substrate, a second structure overlapping the first structure in a vertical direction, and the second structure including a peripheral circuit region. The first structure includes a device isolation structure in the substrate and channel structures extending in a first horizontal direction, spaced apart from each other in a second horizontal direction, the second horizontal direction intersecting the first horizontal direction, each of the channel structures including a channel region, and first and second source/drain regions isolated from each other by the channel region, an insulating pattern between the channel structures, bitlines extending in the vertical direction and contacting first ends of the channel structures, respectively, a gate dielectric layer extending in the second horizontal direction and surrounding the channel region of the channel structures, a gate electrode extending in the second horizontal direction and surrounding the gate dielectric layer, data storage structures contacting second ends of the channel structures, the second ends opposing the first ends of the channel structures, and a plate electrode connected to the data storage structures, and the plate electrode extending in the second horizontal direction and further extending in the vertical direction. The device isolation structure includes a first device isolation pattern having an upper surface in contact with a lower surface of the bitlines, and the first device isolation pattern extending in the second horizontal direction, a second device isolation pattern having an upper surface in contact with a lower surface of the plate electrode, and the second device isolation pattern extending in the second horizontal direction, and third device isolation patterns overlapping the insulating pattern in the vertical direction, extending in the first horizontal direction between the first device isolation pattern and the second device isolation pattern, and spaced apart from each other in the second horizontal direction. At least one of the first device isolation pattern, the second device isolation pattern, and the third device isolation patterns penetrates the substrate.

### BRIEF DESCRIPTION OF DRAWINGS

The above and other aspects, features, and advantages of the present disclosure will be more clearly understood from the following detailed description, taken in combination with the accompanying drawings, in which:

FIG. 1 is a perspective diagram illustrating a semiconductor device according to some example embodiments of the present disclosure;

FIG. 2 is a circuit diagram illustrating a memory cell in a memory cell array region according to some example embodiments of the present disclosure;

FIG. 3 is a plan diagram illustrating a semiconductor device according to some example embodiments of the present disclosure;

FIG. 4 is a perspective diagram illustrating a semiconductor device according to some example embodiments of the present disclosure;

FIG. 5 is a vertical cross-sectional diagram illustrating a semiconductor device illustrated in FIG. 3 taken along line I-I′;

FIG. 6 is a vertical cross-sectional diagram illustrating a semiconductor device illustrated in FIG. 3 taken along line II-II′;

FIG. 7 is a vertical cross-sectional diagram illustrating a semiconductor device illustrated in FIG. 3 taken along line III-III′;

FIG. 8A is an enlarged diagram illustrating a semiconductor device illustrated in FIG. 5 according to some example embodiments of the present disclosure;

FIG. 8B is an enlarged diagram illustrating a semiconductor device illustrated in FIG. 6 according to some example embodiments of the present disclosure;

FIG. 9A is an enlarged diagram illustrating a semiconductor device illustrated in FIG. 5 according to some example embodiments of the present disclosure;

FIG. 9B is an enlarged diagram illustrating a semiconductor device illustrated in FIG. 6 according to some example embodiments of the present disclosure;

FIG. 10 is an enlarged diagram illustrating a semiconductor device illustrated in FIG. 6 according to some example embodiments of the present disclosure; and

FIGS. 11, 12, and 13 are enlarged diagrams illustrating a semiconductor device illustrated in FIG. 5 according to some example embodiments of the present disclosure.

### DETAILED DESCRIPTION

Hereinafter, some example embodiments of the present disclosure will be described as follows with reference to the accompanying drawings.

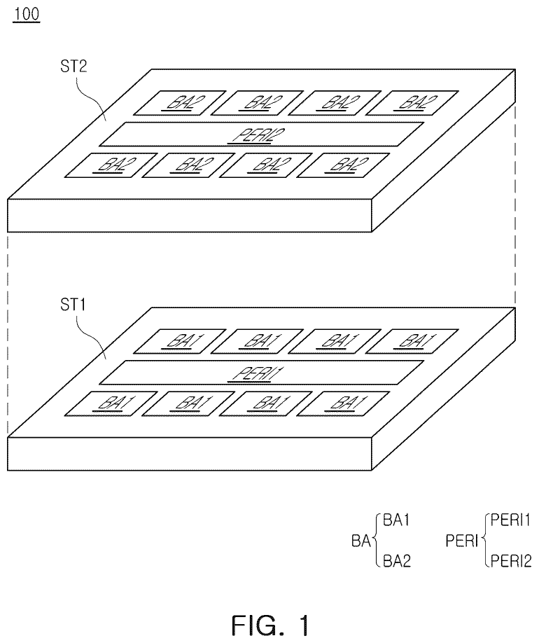

FIG. 1 is a perspective diagram illustrating a semiconductor device according to some example embodiments.

Referring to FIG. 1, a semiconductor device 100 may include a first structure ST1 and a second structure ST2 vertically overlapping the first structure ST1. The second structure ST2 may be disposed on the first structure ST1.

The first structure ST1 may be a first chip structure including memory cells MC, and the second structure ST2 may be a second chip structure including a peripheral circuit which may operate the memory cells MC. The first structure ST1 and the second structure ST2 may be formed by bonding by a bonding process such as a wafer bonding process. Accordingly, the first structure ST1 may be in contact with and bonded to the second structure ST2.

The semiconductor device 100 may include a plurality of banks BA and peripheral circuit regions PERI. The peripheral circuit region PERI may include a first peripheral circuit region PERI in the first structure ST1 and a second peripheral circuit region PERI2 in the second structure ST2. The peripheral circuit region PERI may be a peripheral circuit region in which peripheral circuits for input/output of data or commands, or input of power/ground are disposed.

Each of the plurality of banks BA may include a first bank region BA1 in the first structure ST1 and a second bank region BA2 in the second structure ST2.

The first bank region BA1 in the first structure ST1 may include memory cell array regions. The memory cell array regions may include memory cells MC. The memory cell array regions may be arranged in the first direction (X-direction) and the second direction (Y-direction). The first direction (X-direction) and the second direction (Y-direction) may be perpendicular to each other. The first direction (X-direction) and the second direction (Y-direction) may be referred to as a horizontal direction, and the third direction (Z-direction) may be referred to as a vertical direction.

The second bank region BA2 in the second structure ST2 may include core circuit regions. The core circuit regions may be arranged in the first direction (X-direction) and the second direction (Y-direction). The core circuit regions may include a sense amplifier and sub-wordline drivers.

The first peripheral circuit region PERI1 and the second peripheral circuit region PERI2 may include control circuits which may control the sense amplifiers and the sub-wordline drivers.

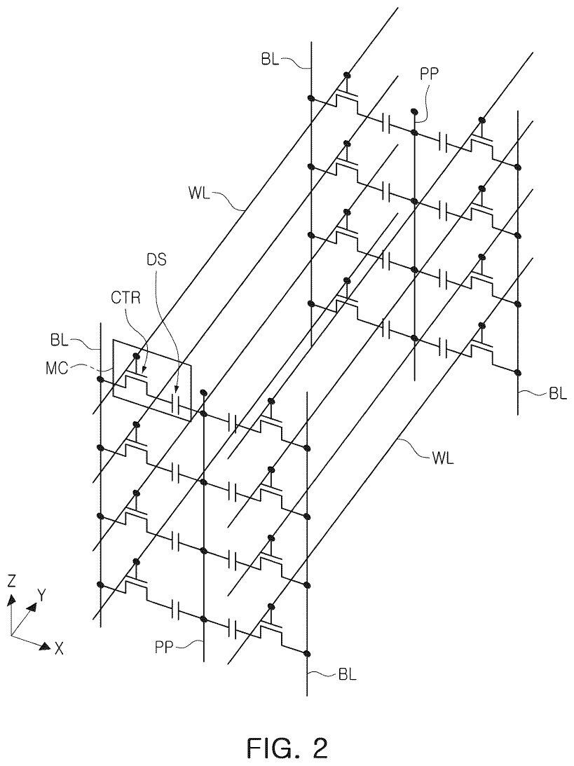

FIG. 2 is a circuit diagram illustrating a memory cell in a memory cell array region according to some example embodiments.

Referring to FIG. 2, the memory cell array region may include memory cells MC arranged in the first direction (X-direction) and the second direction (Y-direction), wordlines WL connected to the memory cells MC and extending in the second direction (Y-direction), and bitlines BL connected to the memory cells MC and extending in the vertical direction (Z-direction). Each of the memory cells MC may include data storage structures DS which may work as a cell transistor CTR and data storage.

The memory cells MC may be a structure in which two or more memory cells are stacked in the vertical direction (Z-direction). In some example embodiments, two memory cells MC may be arranged in the horizontal direction as a pair.

The gate of the cell transistor CTR may be connected to the wordline WL, the first source/drain region of the cell transistor CTR may be connected to the bitline BL, and the second source/drain region of the cell transistor CTR may be connected to the data storage structure DS.

The cell transistor CTR and the data storage structures DS may be disposed in a horizontal arrangement extending in the first direction (X-direction). Adjacent data storage structures DS may share a plate electrode PP. The plate electrode PP may extend in the vertical direction (Z-direction) and may be electrically connected to the data storage structures DS. The plate electrode PP may be vertically oriented. The plate electrode PP may be referred to as a vertical plate electrode. The two memory cells MC arranged in the horizontal direction as a pair may share one plate electrode PP. Each of the data storage structures DS and the plate electrode PP may function as a cell capacitor of each of the memory cells MC. The data storage structures DS and the plate electrode PP may be referred to as a capacitor structure.

The memory cells MC may be disposed between bitlines BL and plate electrode PP. The memory cells MC may be arranged horizontally in the first direction (X-direction). Each of the memory cells MC may be connected to one of bitlines BL, one of wordlines WL, and one of plate electrodes PP.

The wordlines WL may be spaced apart from each other in the first direction (X-direction) and may extend in the second direction (Y-direction). The wordlines WL may be arranged in the vertical direction (Z-direction). In some example embodiments, the wordlines WL may be horizontally oriented with respect to a plane of the first structure ST1. The wordlines WL may be referred to as horizontal wordlines. The plurality of memory cells MC arranged horizontally in the second direction (Y-direction) may be connected to one wordline WL.

The bitlines BL may be spaced apart from each other in the second direction (Y-direction) and may extend in the third direction (Z-direction). The bitlines BL may be vertically oriented from a plane of the second structure ST2. The bitlines BL may be referred to as vertical bitlines. The plurality of memory cells MC arranged vertically in the third direction (Z-direction) may be connected to one bitline BL.

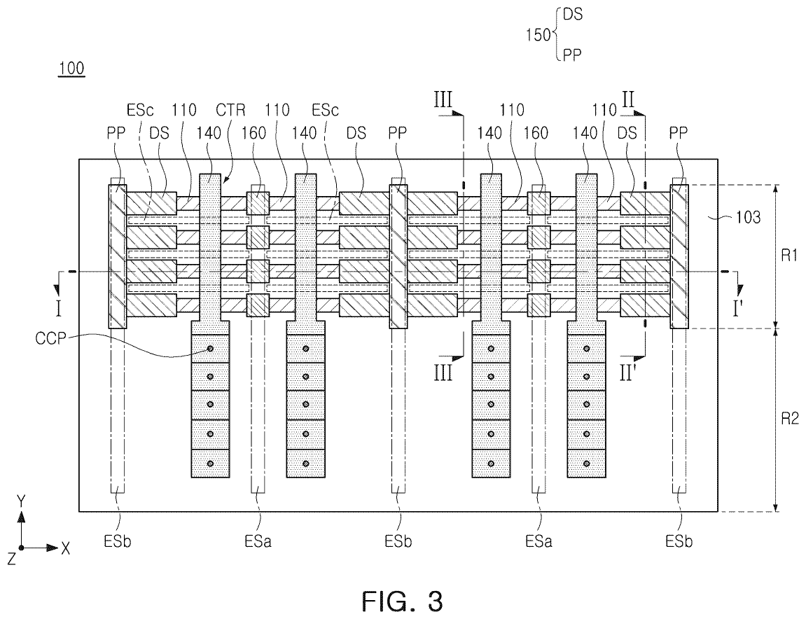

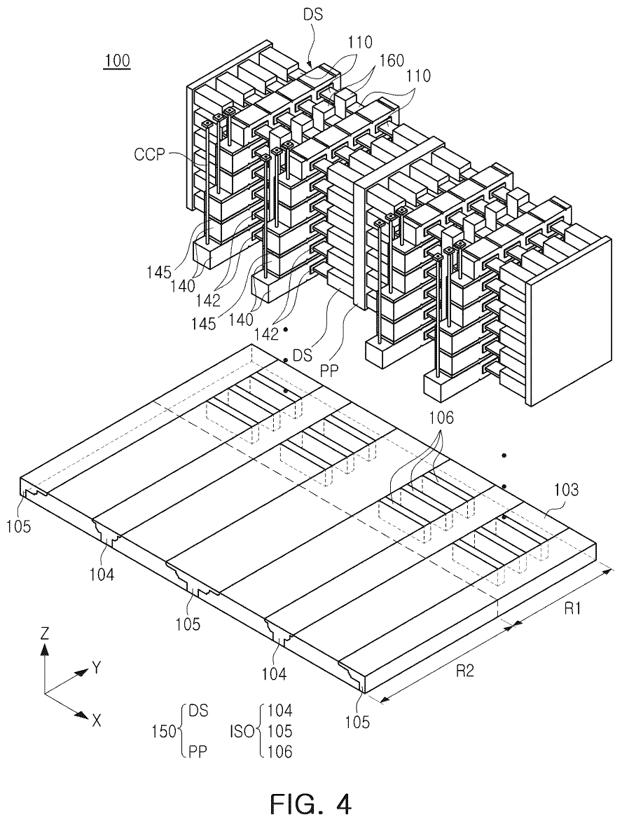

FIG. 3 is a plan diagram illustrating a semiconductor device according to some example embodiments. FIG. 4 is a perspective diagram illustrating a semiconductor device according to some example embodiments.

Referring to FIGS. 3 and 4, the semiconductor device 100 may include a substrate 103 including a memory cell array region R1 and a staircase region R2. In the memory cell array region R1 of the substrate 103, cell transistors CTR disposed between vertical conductive patterns 160 and capacitor structures 150 may be disposed. In the staircase region R2 of the substrate 103, gate electrodes 140 extending by different lengths from the memory cell array region R1 may be disposed. The memory cell array region R1 and staircase region R2 may be disposed side by side in the second direction (Y-direction). In some example embodiments, the memory cell array region R1 may be referred to as a first region, and the staircase region R2 may be referred to as a second region.

The substrate 103 may include a semiconductor material, such as a group IV semiconductor, a group III-V compound semiconductor, or a group II-VI compound semiconductor. The substrate 103 may be provided as a bulk wafer or as an epitaxial layer. For example, the substrate 201 may be bulk silicon or silicon-on-insulator (SOI). However, example embodiments are not limited thereto.

The cell transistor CTR may include channel structures 110, gate electrodes 140, and gate dielectric layers 142 disposed between the channel structures 110 and the gate electrodes 140. The cell transistor CTR may include a gate all around field effect transistor (GAA FET).

The channel structures 110 may include a plurality of channel structures extending in the first direction (X-direction) and spaced apart from each other in the second direction (Y-direction) and the third direction (Z-direction). Four channel structures 110 may be arranged in the second direction (Y-direction) on the same plane (X-Y plane), but example embodiments thereof are not limited thereto, and three or less channel structures or five or more channel structures may be included.

The channel structures 110 may include a semiconductor material, for example, silicon, germanium, or silicon-germanium. However, example embodiments are not limited thereto.

The vertical conductive patterns 160 may include a plurality of vertical conductive patterns extending in the vertical direction (Z-direction) and spaced apart from each other in the second direction (Y-direction). The vertical conductive patterns 160 may be in contact with first ends of the channel structures 110. The vertical conductive patterns 160 may be in contact with the first ends of the channel structures 110 arranged in the vertical direction (Z-direction), respectively.

The vertical conductive patterns 160 may include doped polysilicon, a metal, a conductive metal nitride, a metal-semiconductor compound, a conductive metal oxide, conductive graphene, a carbon nanotube, or a combination thereof. For example, at least one of the vertical conductive patterns 160 may be formed of doped polysilicon, Al, Cu, Ti, Ta, Ru, W, Mo, Pt, Ni, Co, TiN, TaN, WN, NON, TiAl, TiAIN, TiSi, TiSiN, TaSi, TaSiN, RuTiN, NiSi, CoSi, IrOx, RuOx, graphene, carbon nanotubes, or a combination thereof. However, example embodiments are not limited thereto. Each of the vertical conductive patterns 160 may correspond to a bitline BL in FIG. 2.

The capacitor structure 150 may include a data storage structures DS and a plate electrode PP connected to the data storage structures DS.

The data storage structures DS may be in contact with second ends opposing the first ends of the channel structures 110.

The gate electrodes 140 may surround the channel structures 110 disposed between the vertical conductive patterns 160 and the data storage structures DS. Each of the gate electrodes 140 may be disposed as a gate all around (gate all around) structure surrounding the channel structures 110. The gate electrodes 140 may extend in the second direction (Y-direction) and may be spaced apart from each other in the vertical direction (Z-direction). Each of the gate electrodes 140 may surround the channel structures 110 spaced apart from each other in the second direction (Y-direction) on the same plane (X-Y plane). Each of the gate electrodes 140 may correspond to the wordline WL in FIG. 2.

The gate electrodes 140 may be stacked and spaced apart from each other vertically on the memory cell array region R1, and may extend from the memory cell array region R1 to the staircase region R2 with different lengths and may form a step structure having a staircase shape. The gate electrodes 140 may form a step structure between the gate electrodes 140 spaced apart from each other in the third direction (Z-direction) in the second direction (Y-direction). The gate electrode 140 in a lower portion extends longer than the gate electrode 140 in an upper portion, are exposed upwardly from the interlayer insulating layer 145 by the step structure, the gate electrode 140 in lower portion may have region which are in contact with the contact plug CCP, respectively. In some example embodiments, the step structure may be formed by a second gate electrode, a fourth gate electrode, and a sixth gate electrode disposed below the uppermost gate electrode among the gate electrodes 140, a third gate electrode disposed below the uppermost gate electrode may overlap the second gate electrode, and a fifth gate electrode disposed below the gate electrode in an uppermost portion may overlap the fourth gate electrode, thereby forming the step structure. However, example embodiments thereof are not limited thereto, and each of the gate electrodes 140 disposed below the uppermost gate electrode may form the step structure, for example, the third gate electrode disposed below the uppermost gate electrode may extend longer than the second gate electrode disposed below the uppermost gate electrode, thereby forming a staircase structure.

The gate pads may be formed on an upper surface of the second gate electrode disposed below the gate electrode in an uppermost portion among the gate electrodes 140, an upper surface of the fourth gate electrode, and an upper surface of the sixth gate electrode. The contact plugs CCP may be disposed on the gate pads.

The semiconductor device 100 may further include interlayer insulating layers 145 disposed between the gate electrodes 140 stacked and spaced apart from each other in the vertical direction (Z-direction). The interlayer insulating layers 145 may spatially isolate the gate electrodes 140 adjacent to each other in the vertical direction (Z-direction) and may electrically insulate the gate electrodes 140. The interlayer insulating layers 145 may include at least one of an insulating material, for example, silicon nitride, silicon oxynitride, and silicon oxycarbide. However, example embodiments are not limited thereto.

The semiconductor device 100 may further include a gate dielectric layer 142 disposed between the channel structures 110 and the gate electrodes 140. The gate dielectric layer 142 may cover an upper surface, a lower surface, and a side surface of each of the channel structures 110. The gate dielectric layer 142 may include at least one of silicon oxide, silicon nitride, a low-K material, and a high-K material. The high-K material may refer to a dielectric material having a dielectric constant higher than that of silicon oxide, and the low-K material may refer to a dielectric material having a lower dielectric constant than silicon oxide. The high-K material may be, for example, a metal oxide or a metal oxide-nitride. The high-K material may be, for example, at least one of aluminum oxide (Al₂O₃), tantalum oxide (Ta₂O₃), titanium oxide (TiO₂), yttrium oxide (Y₂O₃), zirconium oxide (ZrO₂), zirconium silicon oxide (ZrSiₓO_{y}), hafnium oxide (HfO₂), hafnium silicon oxide (HfSiₓO_{y}), lanthanum oxide (La₂O₃), lanthanum aluminum oxide (LaAlₓO_{y}), lanthanum hafnium oxide (LaHfₓO_{y}), hafnium aluminum oxide (HfAlₓO_{y}), and praseodymium oxide (Pr₂O₃). However, example embodiments are not limited thereto. The gate dielectric layer 142 may be formed as a single layer or multiple layers formed of the materials described above.

The substrate 103 may include first and second device isolation regions ESa, ESb extending in the second direction (Y-direction) across the memory cell array region R1 and the staircase region R2, and third device isolation regions ESc extending in the first direction (X-direction) between the first and second device isolation regions ESa, ESb in the memory cell array region R1. The first and second device isolation regions ESa, ESb may be spaced apart from each other in the first direction (X-direction).

The first device isolation region ESa may overlap the vertical conductive patterns 160 and may extend in the second direction (Y-direction). The first device isolation region ESa may define a region in which the first device isolation pattern 104 is disposed.

The second device isolation region ESb may overlap the plate electrode PP and may extend in the second direction (Y-direction). The second device isolation region ESb may define a region in which the second device isolation pattern 105 is disposed.

The third device isolation region ESc may be disposed between the first device isolation region ESa and the second device isolation region ESb, and may extend in the first direction (X-direction), and the third device isolation region ESc may define a region in which the third device isolation pattern 106 is disposed.

The semiconductor device 100 may further include a device isolation structure ISO having at least a portion disposed in the substrate 103. In some example embodiments, the device isolation structure ISO may include a first device isolation pattern 104 disposed in a first device isolation region ESa of the substrate 103, which overlaps the vertical conductive patterns 160 in the vertical direction (Z-direction), a second device isolation pattern 105 disposed in a second device isolation region ESb of the substrate 103, and overlapping the plate electrode PP and data storage structures DS in the vertical direction (Z-direction), and a third device isolation patterns 106 disposed in each of the third device isolation regions ESc of the substrate 103, and spaced apart from each other in the second direction (Y-direction) between the first device isolation pattern 104 and the second device isolation pattern 105.

The first device isolation pattern 104 may be disposed in the first device isolation region ESa extending in the second direction (Y-direction) from the substrate 103, and may overlap the vertical conductive patterns 160 in the vertical direction (Z-direction).

The second device isolation pattern 105 may be disposed in the second device isolation region ESb extending in the second direction (Y-direction) from the substrate 103, and may overlap the plate electrode PP in the vertical direction (Z-direction). The second device isolation pattern 105 may be spaced apart in the first direction (X-direction) from the first device isolation pattern 104 with the third device isolation patterns 106 interposed therebetween.

Each of the first device isolation pattern 104 and the second device isolation pattern 105 may extend in the second direction (Y-direction) and may be disposed from the memory cell array region R1 to the staircase region R2.

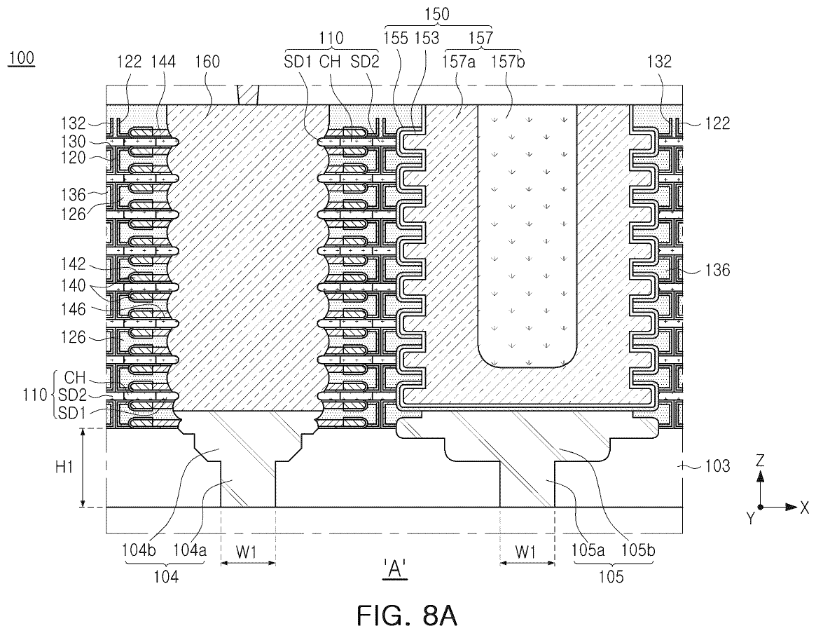

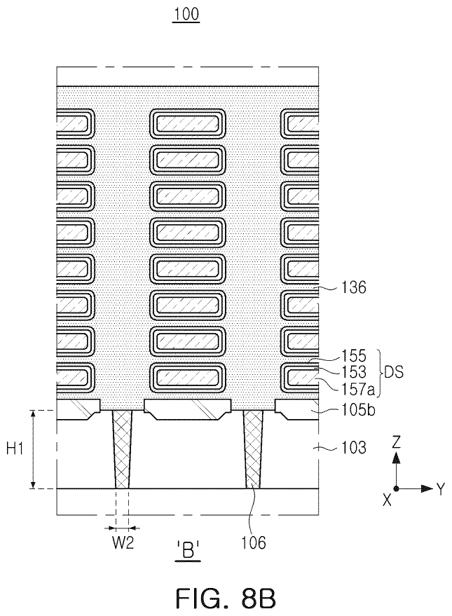

The third device isolation patterns 106 may be disposed in third device isolation regions ESc extending in the first direction (X-direction) between the first device isolation region ESa and the second device isolation region ESb on the substrate 103, and may overlap insulating patterns disposed between the channel structures 110 (e.g., the first and second gap-fill insulating layers 126 and 136 in FIG. 8A). The third device isolation patterns 106 may not overlap the channel structures 110 and the data storage structures DS in the vertical direction (Z-direction). In some example embodiments, the third device isolation patterns 106 may be disposed only on the memory cell array region R1, and may not be disposed on the staircase region R2. However, example embodiments thereof are not limited thereto, and in some example embodiments, the third device isolation patterns 106 may be disposed between the first device isolation pattern 104 and the second device isolation pattern 105 disposed on the staircase region R2.

At least one of the first device isolation pattern 104, the second device isolation pattern 105, and the third device isolation patterns 106 may penetrate the substrate 103. In some example embodiments, the first device isolation pattern 104, the second device isolation pattern 105, and the third device isolation patterns 106 may penetrate the substrate 103. That is, a lower surface of the first device isolation pattern 104, a lower surface of the second device isolation pattern 105, and a lower surface of the third device isolation patterns 106 may be exposed from a lower surface of the substrate 103 such that, the lower surfaces of the first, second, and third device isolation patterns 104, 105, and 106 may be between, and not vertically overlapping with, the lower surfaces of the substrate 103.

A memory cell (e.g., the memory cell MC in FIG. 2) may include a first device isolation pattern 104 disposed on a lower surface of vertical conductive patterns 160, a second device isolation pattern 105 disposed on a lower surface of plate electrode PP, and a third device isolation patterns 106 disposed on a lower portion of insulating patterns (e.g., the first and second gap-fill insulating layers 126 and 136 in FIG. 8A) between channel structures 110 spaced apart from each other in the second direction (Y-direction). In some example embodiments, as a memory cell shares a plate electrode PP with an adjacent memory cell, a memory cell may also share a second device isolation pattern 105 disposed on a lower portion of the plate electrode PP.

According to some example embodiments, a semiconductor device 100 may use at least one of first, second, and third device isolation patterns 104 and 105, and 106 of the device isolation structure ISO disposed in the substrate 103 as an etch-stop layer in a process of polishing the substrate 103, and at least one of the first, second, and third device isolation patterns 104 and 105, and 106 may have a lower surface coplanar (and/or substantially coplanar) with a lower surface of the substrate 103. Accordingly, using at least one of the first, second, and third device isolation patterns 104 and 105, and 106 of the device isolation structure ISO as an etch-stop layer, process efficiency may be increased, and the thickness of substrate 103 may be reduced, such that a size of the semiconductor device may also be reduced.

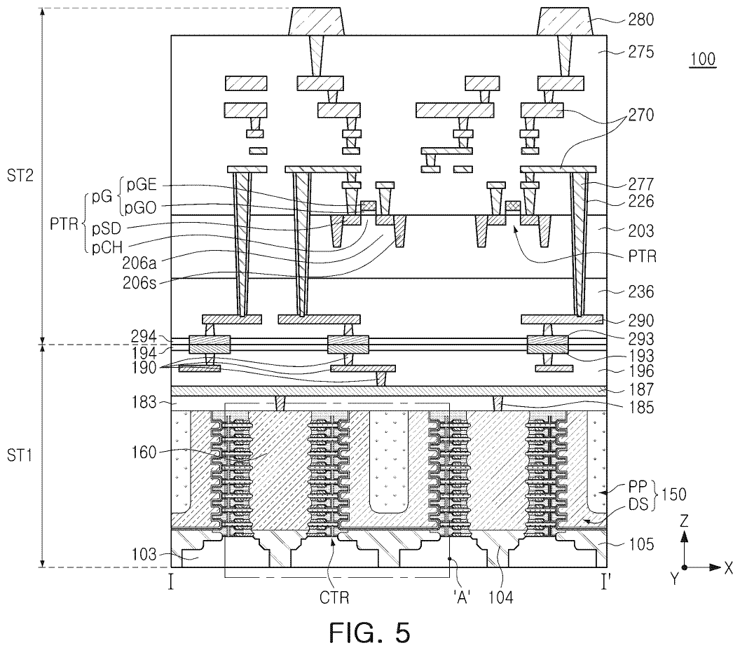

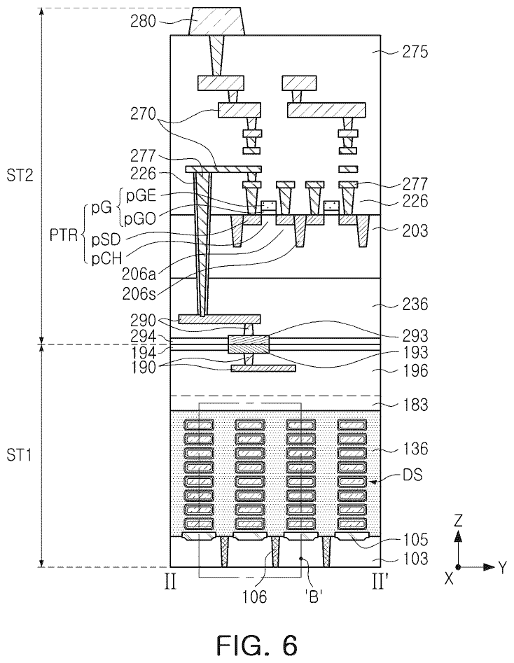

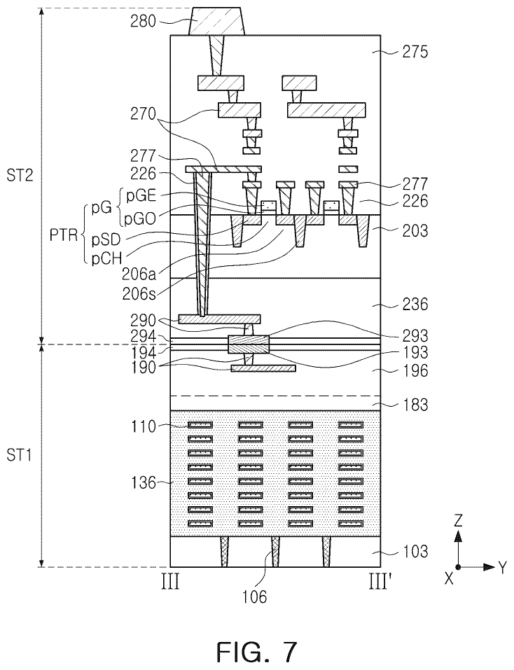

FIG. 5 is a vertical cross-sectional diagram illustrating a semiconductor device illustrated in FIG. 3 taken along line I-I′. FIG. 6 is a vertical cross-sectional diagram illustrating a semiconductor device illustrated in FIG. 3 taken along line II-II′. FIG. 7 is a vertical cross-sectional diagram illustrating a semiconductor device illustrated in FIG. 3 taken along line III-III′. FIG. 8A is an enlarged diagram illustrating a semiconductor device illustrated in FIG. 5 according to some example embodiments. FIG. 8B is an enlarged diagram illustrating a semiconductor device illustrated in FIG. 6 according to some example embodiments. FIG. 8A may correspond to area A of FIG. 5, and FIG. 8B may correspond to area B of FIG. 6.

Referring to FIGS. 5 to 8B, the semiconductor device 100 may include a first structure ST1 and a second structure ST2 vertically overlapping the first structure ST1. The first structure ST1 may be an example of the first structure ST1 described in FIG. 1, and the second structure ST2 may be an example of the second structure ST2 described in FIG. 1.

The first structure ST1 may be a memory region including memory cells arranged three-dimensionally, and the second structure ST2 may be a peripheral region including peripheral circuits.

The first structure ST1 may include a substrate 103, cell transistors CTR disposed on the substrate 103, vertical conductive patterns 160, and capacitor structures 150.

The capacitor structures 150 of the first structure ST1 may be spaced apart from each other in the first direction (X-direction). One of the vertical conductive patterns 160 may be disposed between a pair of adjacent capacitor structures 150.

The first structure ST1 may include channel structures 110 stacked and spaced apart from each other in the vertical direction (Z-direction). Each of the channel structures 110 may include a first source/drain region SD1 adjacent to the vertical conductive pattern 160, a second source/drain region SD2 adjacent to the capacitor structure 150, and a channel region CH disposed between the first source/drain region SD1 and the second source/drain region SD2.

The first structure ST1 may include gate electrodes 140 stacked and spaced apart from each other in the vertical direction (Z-direction). The gate electrodes 140 may overlap the channel region CH of the channel structures 110 in the vertical direction (Z-direction). Each of the gate electrodes 140 may surround the channel region CH and extend in the second direction (Y-direction).

The first structure ST1 may further include a gate dielectric layer 142, a gate capping layer 144, and an insulating layer 146. The gate dielectric layer 142 may be disposed between the gate electrodes 140 and the channel structures 110. The gate dielectric layer 142 may be disposed as a gate all around structure surrounding the channel structure 110 and may cover an upper surface, lower surface, and side surface of the gate electrode 140. The gate capping layer 144 may be disposed between the gate electrode 140 and the vertical conductive pattern 160. A portion of the gate dielectric layer 142 may be disposed between the gate capping layer 144 and the channel structure 110. The insulating layer 146 may be disposed between the gate capping layer 144 and the first source/drain region SD1 of the channel structure 110.

The gate capping layers 144 may include at least one of an insulating material, for example, silicon nitride, silicon oxynitride, and silicon oxycarbide. However, example embodiments are not limited thereto.

The first structure ST1 may further include a first buffer layer 120, a first liner 122, and a first gap-fill insulating layer 126 disposed between the channel structures 110. The first buffer layer 120, the first liner 122, and the first gap-fill insulating layer 126 may be in contact with the gate dielectric layer 142. For example, the first buffer layers 120 may extend in a horizontal direction on the upper surface and the lower surface of the channel structures 110 and may extend in the vertical direction (Z-direction) between the channel structures 110. The first liner 122 may be conformally disposed on the first buffer layer 120. The first gap-fill insulating layer 126 may fill a space between adjacent gate dielectric layers 142. The first gap-fill insulating layer 126 may be in contact with the gate capping layer 144 and the vertical conductive pattern 160. The first buffer layer 120 and the first gap-fill insulating layer 126 may include silicon oxide, and the first liner 122 may include silicon nitride.

The first structure ST1 may further include a second buffer layer 130, a second liner 132, and a second gap-fill insulating layer 136 disposed between the channel structures 110. In some example embodiments, the second buffer layer 130, the second liner 132, and the second gap-fill insulating layer 136 may be in contact with the first electrode 155 of the capacitor structure 150. For example, the second buffer layers 130 may extend horizontally on the upper surface and lower surface of the channel structures 110, and may extend vertically (Z-direction) between the channel structures 110. The second liner 132 may be conformally disposed on the second buffer layer 130, and the second gap-fill insulating layer 136 may be disposed on the second liner 132 and may fill a space between the channel structures 110 and the first electrodes 155 adjacent to each other. The first gap-fill insulating layer 126 and the second gap-fill insulating layer 136 may correspond to the interlayer insulating layer 145 in FIG. 4. The second buffer layer 130 and the second gap-fill insulating layer 136 may include silicon oxide, and the second liner 132 may include silicon nitride.

The vertical conductive patterns 160 may extend in the vertical direction (Z-direction) on the substrate 103. The vertical conductive patterns 160 may be spaced apart from each other in the first direction (X-direction) and the second direction (Y-direction). The channel structures 110 stacked in the vertical direction (Z-direction) may be electrically connected to one vertical conductive pattern 160. For example, the vertical conductive patterns 160 may be electrically connected to the first source/drain regions SD1 of the channel structures 110.

The first structure ST1 may include capacitor structures 150. Each of the capacitor structures 150 may include first electrodes 155, a second electrode 157, and a dielectric layer 153 disposed between the first electrodes 155 and the second electrode 157.

The first electrodes 155 may be electrically connected to the second source/drain regions SD2 of the channel structures 110. Each of the first electrodes 155 may have a cylindrical shape oriented in a horizontal direction.

The second electrode 157 may include a 2-1 electrode material layer 157a in contact with the dielectric layer 153 and a 2-2 electrode material layer 157b in contact with the 2-1 electrode material layer 157a.

The dielectric layer 153 may be disposed between the first electrode 155 and the 2-1 electrode material layer 157a, and may extend in the vertical direction (Z-direction) from an inner wall of the first electrodes 155 to conformally cover the first electrodes 155. The 2-1 electrode material layer 157a may be disposed on an inner wall of the first electrodes 155 on the dielectric layer 153. The 2-2 electrode material layer 157b may be disposed on the 2-1 electrode material layer 157a, and may be disposed in a form of extending in the vertical direction (Z-direction) between the first electrodes 155 spaced apart from each other in the horizontal direction.

The first electrode 155 and the second electrode 157 may include a metal, a metal oxide, a metal nitride, a metal carbide, a metal silicide, or a combination thereof. The dielectric layer 153 may be referred to as a capacitor dielectric layer, and may include silicon oxide, silicon nitride, a high-K material, or a combination thereof. The high-K material may have a permittivity higher than that of silicon oxide.

The first electrode 155, the dielectric layer 153, and the 2-1 electrode material layer 157a may form the data storage structures DS in FIGS. 3 and 4. The 2-1 electrode material layer 157a and the 2-2 electrode material layer 157b may represent the plate electrode PP in FIGS. 3 and 4, and the 2-2 electrode material layer 157b may have substantially the same shape as that of the plate electrode PP in FIGS. 3 and 4, but example embodiments thereof are not limited thereto.

The first structure ST1 may further include a device isolation structure disposed in the substrate 103 (e.g., the device isolation structure ISO in FIG. 4).

The device isolation structure may include first device isolation patterns 104 in contact with a lower surface of each of the vertical conductive patterns 160, second device isolation patterns 105 in contact with a lower surface of capacitor structures 150, and third device isolation patterns 106 disposed in a lower portion of the insulating pattern between the first device isolation patterns 104 and the second device isolation patterns 105 and disposed between data storage structures (e.g., data storage structures DS in FIG. 3) and between channel structures 110.

The first device isolation pattern 104 may overlap the vertical conductive pattern 160 and may have an upper surface in contact with a lower surface of the vertical conductive pattern 160. In some example embodiments, the first device isolation pattern 104 may include a first portion 104a and second portions 104b extending from the first portion 104a and in contact with a lower surface of a vertical conductive pattern 160. In some example embodiments, the first portion 104a may have a first width W1 in the first direction (X-direction), each of the second portions 104b may extend from the first portion 104a and may have a width in the first direction (X-direction) greater than the first width W1 and the width may increase upwardly. The first portion 104a may overlap the first device isolation region ESa in FIG. 3, may extend in the second direction (Y-direction), and each of the second portions 104b may be in contact with a lower surface of each of the vertical conductive patterns 160. The second portions 104b may be spaced apart from each other in the second direction (Y-direction) on the first portion 104a.

The second device isolation pattern 105 may have an upper surface overlapping the capacitor structure 150 and in contact with a lower surface of the capacitor structure 150. In some example embodiments, the second device isolation pattern 105 may include a third portion 105a and fourth portions 105b extending from the third portion 105a and in contact with a lower surface of the capacitor structures 150. The third portion 105a may have a first width W1 in the first direction (X-direction). The fourth portions 105b may extend from the third portion 105a and may have a width greater than the first width W1 in the first direction (X-direction). The third portion 105a may extend in the second direction (Y-direction) and overlap the second device isolation region ESb in FIG. 3 and may overlap the 2-2 electrode material layer 157b (or, e.g., the plate electrode PP in FIGS. 3 and 4) in the vertical direction (Z-direction). The fourth portions 105b may extend in the second direction (Y-direction) on the third portion 105a and may be in contact with the lower surface of the capacitor structure 150. In some example embodiments, an upper surface of each of the fourth portions 105b may be in contact with the first electrode 155. The fourth portions 105b may be spaced apart from each other in the second direction (Y-direction) on the third portion 105a.

An upper surface of the first device isolation pattern 104 and an upper surface of the second device isolation pattern 105 may be disposed at a level higher than a level of an upper surface of the substrate 103. The upper surfaces of the first and second device isolation patterns 104 and 105 may be disposed at a level lower than a level of the channel structure 110 in the lowermost portion. In some example embodiments, a side surface of the second portion 104b of the first device isolation pattern 104 exposed on the upper surface of the substrate 103 may be in contact with the gate capping layer 144, the insulating layer 146, and the first gap-fill insulating layer 126 in the lowermost portion. A side surface of the fourth portion 105b of the second device isolation pattern 105 exposed on the upper surface of the substrate 103 may be in contact with the second buffer layer 130, the second liner 132, and the second gap-fill insulating layer 136.

In some example embodiments, each of the first portion 104a of the first device isolation pattern 104 and the third portion 105a of the second device isolation pattern 105 may have the same width as the first width W1 in the first direction (X-direction). However, example embodiments thereof are not limited thereto, and in some example embodiments, a width of the first portion 104a of the first device isolation pattern 104 in the first direction (X-direction) may be different from a width of the third portion 105a of the second device isolation pattern 105 in the first direction (X-direction). In some example embodiments, a height of the first portion 104a of the first device isolation pattern 104 in the vertical direction may be the same as a height of a third portion 105a of the second device isolation pattern 105 in the vertical direction. However, example embodiments thereof are not limited thereto, and a height of the first portion 104a of the first device isolation pattern 104 in the vertical direction may be different from a height of the third portion 105a of the second device isolation pattern 105 in the vertical direction.

The third device isolation patterns 106 may be disposed between the first device isolation pattern 104 and the second device isolation pattern 105 disposed on the memory cell array region R1, may extend in the first direction (X-direction), and may be spaced apart from each other in the second direction (Y-direction). The third device isolation patterns 106 may overlap the second gap-fill insulating layer 136 filling the channel structures 110. The third device isolation patterns 106 may not overlap the channel structures 110 and data storage structures (e.g., the data storage structures DS in FIG. 3). The third device isolation patterns 106 spaced apart from each other in the second direction (Y-direction) may overlap gate electrodes 140 spaced apart from each other in the vertical direction (Z-direction) between the capacitor structure 150 and the vertical conductive patterns 160. In some example embodiments, each of the third device isolation patterns 106 may have a width decreasing toward the lower surface of the substrate 103.

The upper surface of the third device isolation patterns 106 may be coplanar (and/or substantially coplanar) with the upper surface of the substrate 103. The lower surface of each of the third device isolation patterns 106 may have a second width W2 in the second direction (Y-direction). The second width W2 of the third device isolation pattern 106 may be smaller than the first width W1 of the lower surface of the first device isolation pattern 104 and the first width W1 of the lower surface of the second device isolation pattern 105. For example, the first width W1 may be about twice the second width W2.

The first device isolation pattern 104, the second device isolation pattern 105, and the third device isolation patterns 106 may penetrate the substrate 103. The lower surface of the first device isolation pattern 104, the lower surface of the second device isolation pattern 105, and the lower surface of the third device isolation pattern 106 may be exposed from the lower surface of the substrate 103. Such that, the lower surfaces of the first, second, and third device isolation patterns 104, 105, and 106 may be between, and not vertically overlapping with, the lower surfaces of the substrate 103. In some example embodiments, the lower surface of the first device isolation pattern 104, the lower surface of the second device isolation pattern 105, and the lower surface of the third device isolation pattern 106 may be coplanar (and/or substantially coplanar) with the lower surface of the substrate 103.

The heights in the vertical direction (Z-direction) of the first and second device isolation patterns 104 and 105 may be greater than a first height H1 in the vertical direction (Z-direction) of the substrate 103. In some example embodiments, the height in the vertical direction (Z-direction) of the third device isolation pattern 106 may be the same as the first height H1 of the substrate 103.

The first device isolation pattern 104, the second device isolation pattern 105, and the third device isolation pattern 106 may include the same insulating material. For example, the insulating material may include silicon oxide, silicon nitride, silicon oxynitride, silicon carbonitride, a low-K dielectric, or a combination thereof. However, example embodiments are not limited thereto.

According to some example embodiments, the semiconductor device 100 may use the first device isolation pattern 104, the second device isolation pattern 105, and the third device isolation patterns 106 disposed in the substrate 103 as etch-stop layers in a process of polishing the substrate 103. Accordingly, the lower surfaces of the first, second, and third device isolation patterns 104 and 105, and 106 may be coplanar (and/or substantially coplanar) with the lower surface of the substrate 103. Using the first, second and third device isolation patterns 104, 105 and 106 as etch-stop layers without an etch-stop layer, process efficiency may be increased, and the thickness of the substrate 103 may be reduced, thereby reducing the size of the semiconductor device.

The first structure ST1 may further include an insulating layer 183 covering the vertical conductive patterns 160 and capacitor structures 150, contact plugs 185 penetrating the insulating layer 183 and connected to the vertical conductive patterns 160, and a conductive line 187 disposed on the insulating layer 183 and connected to the contact plugs 185.

The conductive line 187 may extend in the first direction (X-direction). The conductive line 187 may electrically connect the vertical conductive patterns 160 arranged in the first direction (X-direction) through the contact plugs 185.

The first structure ST1 may further include an insulating structure 196 on a conductive line 187, interconnection structures 190 buried in the insulating structure 196, a first bonding insulating layer 194, and first bonding metal layers 193 having an upper surface coplanar (and/or substantially coplanar) with an upper surface of the first bonding insulating layer 194. The second structure ST2 may include peripheral circuits, such as a sense amplifier and a sub-wordline driver, in the second bank region BA2 described in FIG. 1. For example, the second structure ST2 may include peripheral transistors PTR included in a peripheral circuit. For example, the first source/drain regions SD1 of the cell transistor CTR disposed in the first structure ST1 may be electrically connected to the peripheral transistor PTR included in a sense amplifier disposed in the second structure ST2 through the vertical conductive pattern 160 and the conductive line 187. In some example embodiments, electrical connection relationship between the peripheral transistors PTR and the cell transistor CTR may be merely an example, and example embodiments thereof are not limited to the structure in FIG. 5.

The second structure ST2 may further include a semiconductor body 203, a peripheral device isolation region 206s defining a peripheral active region 206a on the semiconductor body 203, peripheral source/drain regions pSD disposed in the peripheral active region 206a, a peripheral channel region pCH between the peripheral source/drain regions pSD, and a peripheral gate pG including a peripheral gate dielectric layer pGO and a peripheral gate electrode pGE disposed in order on the peripheral channel region pCH.

Each of the peripheral transistors PTR may include the peripheral source/drain regions PSD, the peripheral channel region pCH, and the peripheral gate pG.

The second structure ST2 may further include a lower portion insulating layer 236 below the semiconductor body 203, a redistribution structure 290 buried in the lower insulating layer 236, a second bonding insulating layer 294, and second bonding metal layers 293 connected to the redistribution structure 290 and having lower surfaces coplanar (and/or substantially coplanar) with a lower surface of the second bonding insulating layer 294.

The first bonding insulating layer 194 may be bonded and connected to the second bonding insulating layer 294. The first and second bonding insulating layers 194 and 294 may include at least one of, for example, SiO, SiN, SiCN, SiOC, SiON, and SiOCN. However, example embodiments are not limited thereto. The second bonding metal layers 293 may be bonded to and in contact with the first bonding metal layers 193. The first and second bonding metal layers 193 and 293 may include a metal material, for example, copper.

The first structure ST1 and the second structure ST2 may be bonded to each other by bonding between the first bonding insulating layer 194 and the second bonding insulating layer 294 and bonding between the first bonding metal layers 193 and the second bonding metal layers 293. The bonding between the first bonding metal layers 193 and the second bonding metal layers 293 may be copper (Cu)-copper (Cu) bonding, and the bonding between the first bonding insulating layer 194 and the second bonding insulating layer 294 may be dielectric-dielectric bonding, for example, SiCN—SiCN bonding. The first and second structures ST1, ST2 may be bonded to each other by hybrid bonding including copper (Cu)-copper (Cu) bonding and dielectric-dielectric bonding. However, example embodiments thereof are not limited thereto, and the first and second bonding metal layers 193 and 293 may not be provided, and the first structure ST1 and the second structure ST2 may be bonded to each other only by bonding the first and second bonding insulating layers 194 and 294. In this case, a through-via 277 of the second structure ST2 may be directly connected to the interconnection structures 190 of the first structure ST1.

The second structure ST2 may further include an upper insulating structure 275 on the semiconductor body 203, a peripheral interconnection structure 270 buried in the upper insulating structure 275 and electrically connected to the peripheral transistors PTR included in the peripheral circuit, and upper interconnections 280 on the upper insulating structure 275.

The second structure ST2 may further include through-vias 277 penetrating the semiconductor body 203 and electrically connecting the peripheral interconnection structures 270 to the redistribution structure 290, and insulating spacers 226 on side surfaces of the through-vias 277.

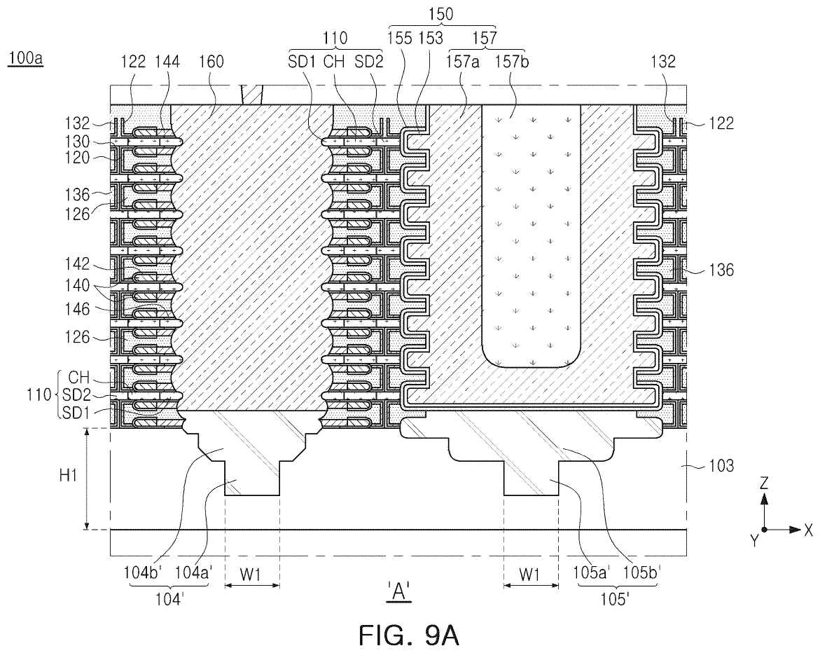

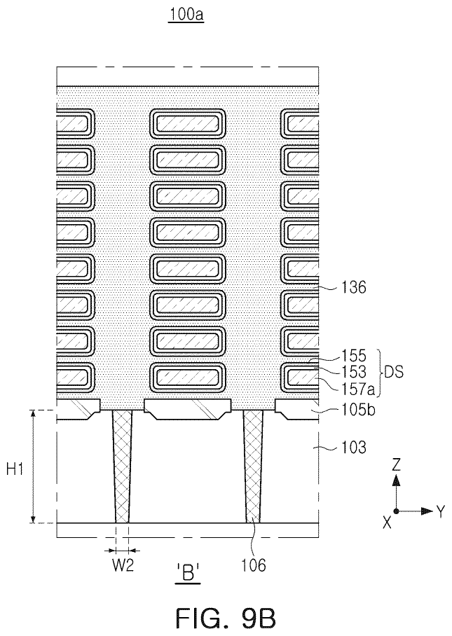

FIG. 9A is an enlarged diagram illustrating a semiconductor device illustrated in FIG. 5 according to some example embodiments. FIG. 9B is an enlarged diagram illustrating a semiconductor device illustrated in FIG. 6 according to some example embodiments.

Referring to FIGS. 9A and 9B, components other than the first device isolation pattern 104′ and the second device isolation pattern 105′ in the substrate 103 may be the same as or may correspond to the components illustrated in FIGS. 5 to 7.

The semiconductor device 100a may include a substrate 103 and first to third device isolation patterns 104′, 105′, and 106 disposed in the substrate 103.

Lower portions of the first and second device isolation patterns 104′ and 105′ may be buried in the substrate 103, and a lower surface of the third device isolation pattern 106 may be exposed from a lower surface of the substrate 103. Such that, the lower surface of the third device isolation patterns 106 may be between, and not vertically overlapping with, the lower surfaces of the substrate 103.

The first device isolation pattern 104′ may overlap the vertical conductive pattern 160 and may have an upper surface in contact with a lower surface of the vertical conductive pattern 160. In some example embodiments, the first device isolation pattern 104′ may include a first portion 104a′ and second portions 104b′ extending from the first portion 104a′ and in contact with a lower surface of the vertical conductive patterns 160 on the first portion 104a′. In some example embodiments, the first portion 104a′ of the first device isolation pattern 104′ may be buried in the substrate 103. A lower surface of the first portion 104a′ may be disposed at a level higher than a level of a lower surface of the substrate 103. The second portion 104b′ of the first device isolation pattern 104′ may have an upper surface extending from the first portion 104a′ and disposed at a level higher than a level of the upper surface of the substrate 103.

The second device isolation pattern 105′ may have an upper surface overlapping the capacitor structure 150 and in contact with a lower surface of the capacitor structure 150. In some example embodiments, the second device isolation pattern 105′ may include a third portion 105a′ and a fourth portion 105b′ extending from the third portion 105a′ and in contact with a lower surface of the capacitor structure 150 on the third portion 105a′. In some example embodiments, the third portion 105a′ of the second device isolation pattern 105′ may be buried in the substrate 103. A lower surface of the third portion 105a′ may be disposed at a level higher than a level of the lower surface of the substrate 103. The fourth portion 105b′ of the second device isolation pattern 105′ may have an upper surface extending from the third portion 105a′ and disposed at a level higher than a level of the upper surface of the substrate 103.

In some example embodiments, the lower surface of the first device isolation pattern 104′ and the lower surface of the second device isolation pattern 105′ may be disposed at a level higher than a level of the lower surface of the substrate 103, and may be disposed at the same level. However, example embodiments thereof are not limited thereto, and the lower surface of the first device isolation pattern 104′ may be disposed at a level different from a level of the lower surface of the second device isolation pattern 105′ in the substrate 103.

The third device isolation pattern 106 may penetrate the substrate 103, and may have a width decreasing toward the lower surface of the substrate 103. In some example embodiments, the third device isolation pattern 106 may have an upper surface coplanar (and/or substantially coplanar) with the upper surface of the substrate 103 and a lower surface coplanar (and/or substantially coplanar) with the lower surface of the substrate 103. In some example embodiments, a height of the third device isolation pattern 106 in the vertical direction (Z-direction) may be the same as a first height H1 of the substrate 103.

A height of the first device isolation pattern 104′ in the vertical direction (Z-direction) and a height of the second device isolation pattern 105′ in the vertical direction (Z-direction) may be less than the first height H1 of the substrate 103. However, example embodiments thereof are not limited thereto.

A semiconductor device 100a according to some example embodiments may include third device isolation patterns 106 disposed in the substrate 103, and the third device isolation patterns 106 may be used as an etch-stop layer in a process of polishing the substrate 103, and accordingly, a lower surface of the third device isolation patterns 106 may be coplanar (and/or substantially coplanar) with the lower surface of the substrate 103. Using the third device isolation patterns 106 as an etch-stop layer without an etch-stop layer, process efficiency may be increased, and the thickness of the substrate 103 may be reduced, and the size of the semiconductor device may be reduced.

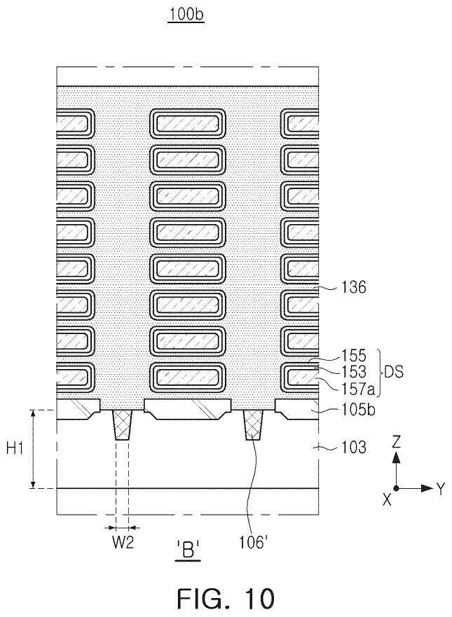

FIG. 10 is an enlarged diagram illustrating a semiconductor device illustrated in FIG. 6 according to some example embodiments.

Referring to FIG. 10, the components other than the third device isolation patterns 106′ in the substrate 103 of a semiconductor device 100b may be the same as or corresponding to the components illustrated in FIGS. 5 to 7.

Referring to FIG. 10 together with FIG. 5, the semiconductor device 100b may include a substrate 103, and a first device isolation pattern 104, a second device isolation pattern 105, and a third device isolation patterns 106′ disposed in the substrate 103. The third device isolation patterns 106′ may be buried in the substrate 103, and lower surfaces of the first and second device isolation patterns 104 and 105 may be exposed from the lower surface of the substrate 103. Such that, the lower surfaces of the first, and second device isolation patterns 104 and 105 may be between, and not vertically overlapping with, the lower surfaces of the substrate 103.

The third device isolation pattern 106′ may have a width decreasing toward the lower surface of the substrate 103. In some example embodiments, the upper surface of the third device isolation pattern 106′ may be coplanar (and/or substantially coplanar) with the upper surface of the substrate 103, and the lower surface of the third device isolation pattern 106′ may be disposed at a level higher than a level of the lower surface of the substrate 103. In some example embodiments, the height of the third device isolation pattern 106′ in the vertical direction (Z-direction) may be smaller than the first height H1 of the substrate 103.

According to some example embodiments, a semiconductor device 100b may include a first device isolation pattern 104 overlapping a vertical conductive pattern 160 disposed in the substrate 103 and a second device isolation pattern 105 overlapping a plate electrode PP, and the first and second device isolation patterns 104 and 105 may be used as etch-stop layers in a process of polishing the substrate 103. Accordingly, a lower surface of the first device isolation pattern 104 and a lower surface of the second device isolation pattern 105 may be coplanar (and/or substantially coplanar) with the lower surface of the substrate 103. Using the first and second device isolation patterns 104 and 105 as etch-stop layers without an etch-stop layer, process efficiency may be increased, and the thickness of the substrate 103 may be reduced, and the size of the semiconductor device may be reduced.

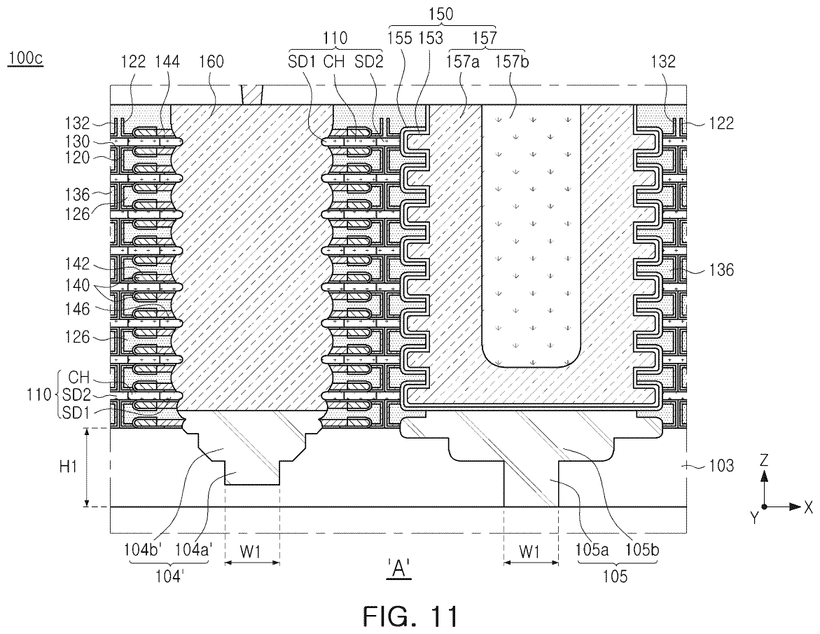

FIGS. 11, 12, and 13 are enlarged diagrams illustrating a semiconductor device illustrated in FIG. 5 according to some example embodiments.

Referring to FIG. 11, the components other than the first device isolation pattern 104′ in the substrate 103 of the semiconductor device 100c may be the same as or correspond to the components illustrated in FIGS. 5 to 7.

Referring to FIG. 11 along with FIGS. 6 and 7, the semiconductor device 100c may include a substrate 103 and a first device isolation pattern 104′, a second device isolation pattern 105, and a third device isolation patterns 106 disposed in the substrate 103. In some example embodiments, a lower surface of the first device isolation pattern 104′ may be buried in the substrate 103, and lower surfaces of the second and third device isolation patterns 105 and 106 may be exposed from the lower surface of the substrate 103. Such that, the lower surfaces of the second, and third device isolation patterns 105 and 106 may be between, and not vertically overlapping with, the lower surfaces of the substrate 103.

A first portion 104a′ of the first device isolation pattern 104′ may be buried in the substrate 103, and a lower surface of the first device isolation pattern 104′ may be disposed at a level higher than a level of the lower surface of the substrate 103, a lower surface of the second device isolation pattern 105, and a lower surface of the third device isolation pattern 106. The lower surface of the second device isolation pattern 105 may be disposed at the same level as the lower surface of the third device isolation patterns 106, and may be coplanar (and/or substantially coplanar) with the lower surface of the substrate 103.

According to some example embodiments, the semiconductor device 100c may include a second device isolation pattern 105 overlapping a plate electrode PP disposed in the substrate 103 and a third device isolation patterns 106, and the second and third device isolation patterns 105 and 106 may be used as an etch-stop layer in a process of polishing the substrate 103. Accordingly, the lower surfaces of the second and third device isolation patterns 105 and 106 may be coplanar (and/or substantially coplanar) with the lower surface of the substrate 103. Using the second and third device isolation patterns 105 and 106 as an etch-stop layer without an etch-stop layer, process efficiency may be increased and the thickness of the substrate 103 may be reduced, thereby also reducing the size of the semiconductor device

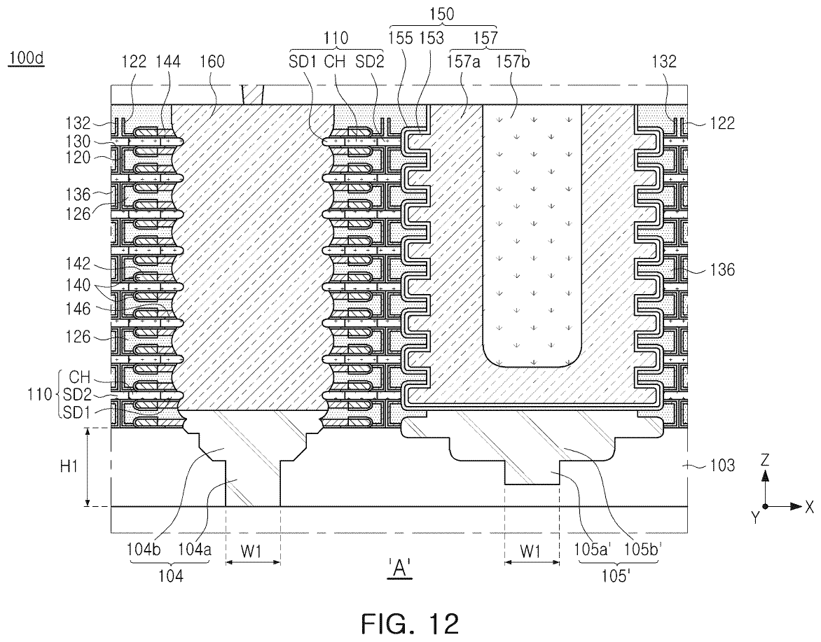

Referring to FIG. 12, components other than the second device isolation pattern 105′ in the substrate 103 of a semiconductor device 100d may be the same as or correspond to the components illustrated in FIGS. 5 to 7.

Referring to FIG. 12 along with FIGS. 6 and 7, a semiconductor device 100d may include a substrate 103 and a first device isolation pattern 104, a second device isolation pattern 105′, and a third device isolation patterns 106 disposed in the substrate 103. In some example embodiments, a lower surface of the second device isolation pattern 105′ may be buried in the substrate 103, and lower surfaces of the first and third device isolation patterns 104 and 106 may be exposed from a lower surface of the substrate 103. Such that, the lower surfaces of the first and third device isolation patterns 104 and 106 may be between, and not vertically overlapping with, the lower surfaces of the substrate 103.

The lower surface of the first device isolation pattern 104 may be disposed at the same level as the lower surface of the third device isolation patterns 106, and may be coplanar (and/or substantially coplanar) with the lower surface of the substrate 103. The third portion 105a′ of the second device isolation pattern 105′ may be buried in the substrate 103, and the lower surface of the second device isolation pattern 105′ may be disposed at a level higher than a level of the lower surface of the substrate 103 and the lower surface of the first device isolation pattern 104.

According to some example embodiments, the semiconductor device 100d may include a first device isolation pattern 104 and a third device isolation patterns 106 disposed in the substrate 103, and the first and third device isolation patterns 104 and 106 may be used as etch-stop layers in a process of polishing the substrate 103. Accordingly, lower surfaces of the first and third device isolation patterns 104 and 106 may be coplanar (and/or substantially coplanar) with the lower surface of the substrate 103. Using the first and third device isolation patterns 104 and 106 as etch-stop layers without an etch-stop layer, process efficiency may be increased, and the thickness of the substrate 103 may be reduced, thereby reducing the size of the semiconductor device.

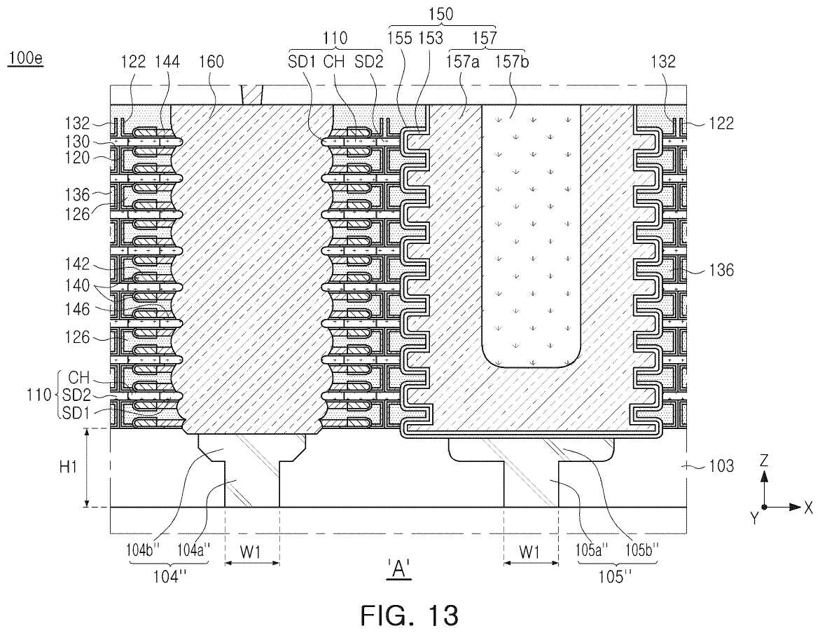

Referring to FIG. 13, the components other than the substrate 103, and the first device isolation pattern 104″ and the second device isolation pattern 105″ in the substrate 103 may be the same as or correspond to the components illustrated in FIGS. 5 to 7.

Referring to FIG. 13 along with FIG. 6, the semiconductor device 100e may include a substrate 103 and a first device isolation pattern 104″, a second device isolation pattern 105″, and a third device isolation pattern 106 buried in the substrate 103.

The first device isolation pattern 104″ may overlap the vertical conductive pattern 160 and may have an upper surface in contact with a lower surface of the vertical conductive pattern 160. In some example embodiments, the first device isolation pattern 104″ may include a first portion 104a″ and a second portion 104b″ extending from the first portion 104a″ on the first portion 104a″ and in contact with a lower surface of the vertical conductive pattern 160. In some example embodiments, the upper surface of the first device isolation pattern 104″ may be disposed at a level lower than a level of the upper surface of the substrate 103. The vertical conductive pattern 160 may extend below the upper surface of the substrate 103. In some example embodiments, the upper surface of the second portion 104b″ of the first device isolation pattern 104″ may be in contact with the vertical conductive pattern 160 at a level lower than a level of the upper surface of the substrate 103. A side surface of the first device isolation pattern 104″ may be surrounded by the substrate 103.

The second device isolation pattern 105″ may have an upper surface overlapping the capacitor structure 150 and in contact with a lower surface of the capacitor structure 150. In some example embodiments, the second device isolation pattern 105″ may include a third portion 105a″ and a fourth portion 105b″ extending from the third portion 105a″ on the third portion 105a″ and in contact with the lower surface of the capacitor structure 150. In some example embodiments, the upper surface of the second device isolation pattern 105″ may be disposed at a level lower than a level of the upper surface of the substrate 103. The lower surface of the capacitor structure 150 may be disposed at a level lower than a level of the upper surface of the substrate 103. The upper surface of the fourth portion 105b″ of the second device isolation pattern 105″ may be in contact with the capacitor structure 150 at a level lower than a level of the upper surface of the substrate 103. The side surface of the second device isolation pattern 105″ may be surrounded by the substrate 103.

In some example embodiments, the upper surfaces of the first and second device isolation patterns 104″ and 105″ may be disposed at a level lower than a level of the upper surface of the third device isolation patterns 106.

A height of the first device isolation pattern 104″ in the vertical direction (Z-direction) and a height of the second device isolation pattern 105″ in the vertical direction (Z-direction) may be less than the first height H1 of the substrate 103. The height of the third device isolation pattern 106 in the vertical direction (Z-direction) may be substantially the same as the first height H1 of the substrate 103.

The first device isolation pattern 104″, the second device isolation pattern 105″, and the third device isolation patterns 106 may penetrate the substrate 103. The lower surface of the first device isolation pattern 104″, the lower surface of the second device isolation pattern 105″, and the lower surface of the third device isolation patterns 106 may be exposed from the lower surface of the substrate 103. Such that, the lower surfaces of the third device isolation patterns 106 may be between, and not vertically overlapping with, the lower surfaces of the substrate 103. The lower surface of the first device isolation pattern 104″, the lower surface of the second device isolation pattern 105″, and the lower surface of the third device isolation patterns 106 may be coplanar (and/or substantially coplanar) with the lower surface of the substrate 103.

According to some example embodiments, the semiconductor device 100e may include a first device isolation pattern 104″ and a second device isolation pattern 105″ extending in the second direction (Y-direction) and disposed in a substrate 103, and a third device isolation patterns 106 extending in the first direction (X-direction) between the first and second device isolation patterns 104″ and 105″, and the first to third device isolation patterns 104″, 105″, and 106 may be used as etch-stop layers in a process of polishing the substrate 103, and accordingly, a lower surface of the first device isolation pattern 104″, a lower surface of the second device isolation pattern 105″, and a lower surface of the third device isolation patterns 106 may be coplanar (and/or substantially coplanar) with the lower surface of the substrate 103. Using the first device isolation pattern 104″, the second device isolation pattern 105″, and the third device isolation patterns 106 as etch-stop layers without an etch-stop layer, process efficiency may be increased and the thickness of the substrate 103 may be reduced, thereby reducing the size of the semiconductor device.

According to some example embodiments of the present disclosure, a method of manufacturing a semiconductor device includes providing a semiconductor structure including a substrate and a memory cell array, starting a polishing process on a backside surface of the semiconductor device, the backside surface being the surface opposite the memory cell array, and stopping the polishing process of the backside surface when an etch-stop layer is exposed from the substrate. The etch-stop layer includes at least one of first device isolation pattern, a second device isolation pattern, and third device isolation pattern, the semiconductor structure further includes a first region and a second region, a device isolation structure in the substrate, channel structures extending in a first horizontal direction on the first region of the substrate, spaced apart from each other in a second horizontal direction, the second horizontal direction intersecting the first horizontal direction, and further spaced apart in a vertical direction, the vertical direction intersecting the first horizontal direction and the second horizontal direction, bitlines extending in the vertical direction on the first region of the substrate, spaced apart from each other in the second horizontal direction, and contacting first ends of the channel structures, respectively, gate electrodes surrounding the channel structures, spaced apart from each other in the vertical direction, extending in the second horizontal direction, and including gate pads arranged in a staircase shape on the second region, data storage structures contacting second ends of the channel structures, the second ends opposing the first ends of the channel structures, and a plate electrode connected to the data storage structures, and the plate electrode extending in the second horizontal direction and the vertical direction. The device isolation structure includes the first device isolation pattern overlapping the bitlines in the vertical direction, and the second device isolation pattern overlapping the plate electrode in the vertical direction, and at least one of a lower surface of the first device isolation pattern and a lower surface of the second device isolation pattern is coplanar with a lower surface of the substrate.

According to some example embodiments of the present disclosure, the etch-stop layer includes the first device isolation pattern, and the second device isolation pattern and third device isolation pattern remain buried after the stopping of the polishing process.

According to some example embodiments of the present disclosure, the etch-stop layer includes the second device isolation pattern, and the first device isolation pattern and third device isolation pattern remain buried after the stopping of the polishing process.

According to some example embodiments of the present disclosure, the etch-stop layer includes the third device isolation pattern, and the first device isolation pattern and second device isolation pattern remain buried after the stopping of the polishing process.

According to the aforementioned example embodiments, in the semiconductor device, using one of the first device isolation pattern overlapping bitlines, a second device isolation pattern overlapping the plate electrodes of a capacitor, and a third device isolation pattern isolating memory cells, as etch-stop layers in the process of polishing the substrate, the thickness of the substrate may be reduced.

It will be understood that elements and/or properties thereof (e.g., structures, surfaces, directions, or the like), which may be referred to as being “perpendicular,” “parallel,” “coplanar,” or the like with regard to other elements and/or properties thereof (e.g., structures, surfaces, directions, or the like) may be “perpendicular,” “parallel,” “coplanar,” or the like or may be “substantially perpendicular,” “substantially parallel,” “substantially coplanar,” respectively, with regard to the other elements and/or properties thereof.

Elements and/or properties thereof (e.g., structures, surfaces, directions, or the like) that are “substantially coplanar” with regard to other elements and/or properties thereof will be understood to be “coplanar” with regard to the other elements and/or properties thereof within manufacturing tolerances and/or material tolerances and/or have a deviation in magnitude and/or angle from “coplanar,” or the like with regard to the other elements and/or properties thereof that is equal to or less than 10% (e.g., a. tolerance of ±10%)).

While some example embodiments have been illustrated and described above, it will be configured as apparent to those skilled in the art that modifications and variations could be made without departing from the scope of the present disclosure as defined by the appended claims.

What is claimed is:

1. A semiconductor device, comprising:
a first structure including a substrate; and
a second structure overlapping the first structure in a vertical direction and including a peripheral circuit,
wherein the first structure includes
a device isolation structure in the substrate,
channel structures extending on the substrate in a first horizontal direction,
the channel structures spaced apart from each other in a second horizontal direction, the second horizontal direction intersecting the first horizontal direction,
an insulating pattern between the channel structures,
bitlines extending in the vertical direction on the substrate and contacting first ends of the channel structures, respectively,
a gate electrode extending in the second horizontal direction and surrounding the channel structures,
data storage structures contacting second ends of the channel structures, the second ends opposing to the first ends of the channel structures and spaced apart from each other in the second horizontal direction, and
a plate electrode connected to the data storage structures and extending in the second horizontal direction and the vertical direction,
the device isolation structure includes
a first device isolation pattern overlapping the bitlines in the vertical direction,
a second device isolation pattern overlapping the plate electrode in the vertical direction, and
third device isolation patterns
overlapping the insulating pattern in the vertical direction,
spaced apart from each other in the second horizontal direction, and
extending between the first device isolation pattern and the second device isolation pattern in the first horizontal direction, and
at least one of the first device isolation pattern, the second device isolation pattern, and the third device isolation patterns penetrates the substrate.

2. The semiconductor device of claim 1, wherein
at least one of a lower surface of the first device isolation pattern, a lower surface of the second device isolation pattern, and a lower surface of the third device isolation patterns is coplanar with a lower surface of the substrate.

3. The semiconductor device of claim 1, wherein
the first device isolation pattern extends in the second horizontal direction and includes an upper surface in contact with a lower surface of the bitlines, and
the second device isolation pattern extends in the second horizontal direction and includes an upper surface in contact with a lower surface of the plate electrode.

4. The semiconductor device of claim 1, wherein
the first device isolation pattern has a first width in the first horizontal direction, and
each of the third device isolation patterns has a second width smaller than the first width in the second horizontal direction.

5. The semiconductor device of claim 4, wherein the second device isolation pattern has a lower surface having the first width in the first horizontal direction.

6. The semiconductor device of claim 1, wherein an upper surface of each of the third device isolation patterns is coplanar with an upper surface of the substrate.

7. The semiconductor device of claim 1, wherein an upper surface of the first device isolation pattern and an upper surface of the second device isolation pattern are at a level higher than a level of an upper surface of the substrate.

8. The semiconductor device of claim 1, wherein each of the third device isolation patterns has a width decreasing in the second horizontal direction toward a lower surface of the substrate.

9. The semiconductor device of claim 1, wherein a lower surface of the first device isolation pattern is at a same level as a level of a lower surface of the second device isolation pattern.

10. The semiconductor device of claim 1, wherein the gate electrode overlaps the third device isolation patterns in the vertical direction.

11. The semiconductor device of claim 1, wherein a lower surface of the first device isolation pattern, a lower surface of the second device isolation pattern, and a lower surface of the third device isolation patterns are exposed from a lower surface of the substrate.

12. The semiconductor device of claim 1, wherein the first device isolation pattern includes a first portion and at least one second portion extending from the first portion and in contact with a lower surface of the bitlines on the substrate.

13. The semiconductor device of claim 1, wherein the second device isolation pattern includes a first portion and at least one second portion extending from the first portion and overlapping the data storage structures and the plate electrode in the vertical direction.

14. The semiconductor device of claim 13, wherein the first portion of the second device isolation pattern does not overlap the data storage structures in the vertical direction.

15. The semiconductor device of claim 1, wherein
a lower surface of the first device isolation pattern and a lower surface of the second device isolation pattern are at a level higher than a level of a lower surface of the substrate, and
a lower surface of the third device isolation patterns is coplanar with a lower surface of the substrate.

16. A semiconductor device, comprising:
a substrate having a first region and a second region;
a device isolation structure in the substrate;
channel structures
extending in a first horizontal direction on the first region of the substrate,
spaced apart from each other in a second horizontal direction, the second horizontal direction intersecting the first horizontal direction, and
further spaced apart in a vertical direction, the vertical direction intersecting the first horizontal direction and the second horizontal direction;
bitlines
extending in the vertical direction on the first region of the substrate,
spaced apart from each other in the second horizontal direction, and
contacting first ends of the channel structures, respectively;
gate electrodes
surrounding the channel structures spaced apart from each other in the second horizontal direction,
spaced apart from in the vertical direction,
extending in the second horizontal direction, and
including gate pads arranged in a staircase shape on the second region;
data storage structures contacting second ends of the channel structures, the second ends opposing the first ends of the channel structures; and
a plate electrode connected to the data storage structures, and the plate electrode extending in the second horizontal direction and the vertical direction,
wherein the device isolation structure includes
a first device isolation pattern overlapping the bitlines in the vertical direction, and
a second device isolation pattern overlapping the plate electrode in the vertical direction, and
at least one of a lower surface of the first device isolation pattern and a lower surface of the second device isolation pattern is coplanar with a lower surface of the substrate.

17. The semiconductor device of claim 16, wherein
each of the first device isolation pattern and the second device isolation pattern extends in the second horizontal direction on the first region and the second region.

18. The semiconductor device of claim 16, further comprising:
third device isolation patterns
between the first device isolation pattern and the second device isolation pattern, and
spaced apart from each other in the second horizontal direction, and
wherein the third device isolation patterns do not overlap the channel structures in the vertical direction.

19. The semiconductor device of claim 16, wherein
each of the data storage structures includes
a first electrode in contact with the second ends of each of the channel structures,
a dielectric layer on the first electrode, and
a second electrode on the dielectric layer,
the plate electrode extends from the data storage structures and includes the first electrode, the dielectric layer, and the second electrode stacked in the vertical direction, and
wherein an upper surface of the second device isolation pattern is contacting the first electrode of each of the data storage structures.

20. A semiconductor device, comprising:
a first structure including a substrate; and
a second structure overlapping the first structure in a vertical direction, and the second structure including a peripheral circuit region,
wherein the first structure includes
a device isolation structure in the substrate,
channel structures
extending in a first horizontal direction,
spaced apart from each other in a second horizontal direction, the second horizontal direction intersecting the first horizontal direction,
each of the channel structures including
a channel region, and
first and second source/drain regions isolated from each other by the channel region,
an insulating pattern between the channel structures,
bitlines extending in the vertical direction and contacting first ends of the channel structures, respectively,
a gate dielectric layer extending in the second horizontal direction and surrounding the channel region of the channel structures,
a gate electrode extending in the second horizontal direction and surrounding the gate dielectric layer,
data storage structures contacting second ends of the channel structures, the second ends opposing the first ends of the channel structures, and
a plate electrode connected to the data storage structures, and the plate electrode extending in the second horizontal direction and further extending in the vertical direction,
the device isolation structure includes
a first device isolation pattern having an upper surface in contact with a lower surface of the bitlines, and the first device isolation pattern extending in the second horizontal direction,
a second device isolation pattern having an upper surface in contact with a lower surface of the plate electrode, and the second device isolation pattern extending in the second horizontal direction, and
third device isolation patterns
overlapping the insulating pattern in the vertical direction,
extending in the first horizontal direction between the first device isolation pattern and the second device isolation pattern, and
spaced apart from each other in the second horizontal direction, and
at least one of the first device isolation pattern, the second device isolation pattern, and the third device isolation patterns penetrates the substrate.
